(19) United States
(12) Patent Application Publication
(10) Pub. No.: US 2026/0114023 A1
(43) Pub. Date: Apr. 23, 2026

(54) SEMICONDUCTOR DEVICES AND METHODS OF FORMING THE SAME

(71) Applicant: Taiwan Semiconductor Manufacturing Company, Ltd., Hsin-Chu (TW)

(72) Inventors: Chih Hsuan Chien, Hsinchu (TW); Yuan-Ching Peng, Hsinchu (TW); Jian-Hao Chen, Hsinchu City (TW); Po Shao Lin, Taipei City (TW); Yung-Hsiang Chan, Taichung (TW); Chia-Yu Tu, Hsinchu City (TW)

(21) Appl. No.: 18/918,273

(22) Filed: Oct. 17, 2024

(51) Int. Cl. H01L 21/8238; H01L 21/02; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/017; H10D 64/018; H10D 84/0167; H10D 84/017; H10D 84/856; H10P 14/6308

(57) ABSTRACT

Semiconductor structures and methods are provided. An exemplary method according to the present disclosure includes forming a plurality of nanostructures over a substrate, depositing a dielectric layer to wrap around the plurality of nanostructures, forming a mask layer over the dielectric layer, etching back the mask layer such that a top surface of the mask layer is coplanar with or lower than a top surface of a topmost nanostructure of the plurality of nanostructures, performing a treatment to reduce a thickness of the topmost nanostructure of the plurality of nanostructures, after the performing of the treatment, selectively removing the mask layer, and forming a gate electrode over the insulation layer and the dielectric layer to wrap around the plurality of nanostructures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. Transistors with different configurations may be suitable for different circuit functions due to their different performance characteristics. While existing transistors and methods for forming transistors are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor structure, according to various embodiments of the present disclosure.

FIG. 2 illustrates a fragmentary top view of an exemplary structure to undergo various stages of operations in the method of FIG. 1, according to various aspects of the present disclosure.

FIGS. 3, 4, 5, 6, 7, 8, 9, 10 and 21A illustrate fragmentary cross-sectional views of the structure taken along line A-A′ as shown in FIG. 2 during various fabrication stages in the method of FIG. 1, according to various aspects of the present disclosure.

FIGS. 11, 12, 13, 14, 15, 16, 17, 18, 19A, 19B, and 20 illustrate fragmentary cross-sectional views of the structure taken along line B-B′ as shown in FIG. 2 during various fabrication stages in the method of FIG. 1, according to various aspects of the present disclosure.

FIG. 21B illustrates a fragmentary cross-sectional view of the structure taken along line C-C′ as shown in FIG. 2 and fabricated according to the method of FIG. 1, according to various aspects of the present disclosure.

FIG. 22 illustrates a fragmentary cross-sectional view of a first alternative structure, according to various aspects of the present disclosure.

FIG. 23A illustrates an exemplary circuit schematic for a static random-access memory (SRAM) cell that includes the structure fabricated according to the method of FIG. 1, according to various aspects of the present disclosure.

FIG. 23B illustrates a fragmentary layout view of the SRAM cell, according to various aspects of the present disclosure.

FIG. 24A illustrates an exemplary circuit schematic for a NOR logic gate that includes the structure fabricated according to the method of FIG. 1, according to various aspects of the present disclosure.

FIG. 24B illustrates a fragmentary layout view of the NOR logic gate, according to various aspects of the present disclosure.

FIG. 25 illustrates a fragmentary cross-sectional view of the NOR logic gate taken along line E-E′ as shown in FIG. 24B, according to various aspects of the present disclosure.

FIG. 26 illustrates a fragmentary cross-sectional view of a second alternative structure, according to various aspects of the present disclosure.

FIG. 27 illustrates a simplified block diagram of a semiconductor structure (e.g., IC package) that includes structures fabricated according to method of FIG. 1, according to various aspects of the present disclosure.

FIG. 28 illustrates fragmentary cross-sectional views of the semiconductor structure shown in FIG. 27, according to various aspects of the present disclosure.

FIG. 29 illustrates a fragmentary cross-sectional view of a third alternative structure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in the figures are perpendicular to one another and are used consistently. Throughout the present disclosure, like reference numerals denote like features unless otherwise excepted.

An N-type transistor (e.g., NFET) includes a pair of N-type doped source/drain features, and its majority carrier is electrons. A P-type transistor (PFET) includes a pair of P-type doped source/drain features, and its majority carrier is holes. For NFETs and PFETs have same configurations (e.g., effective channel widths, effective channel thicknesses, gate lengths), PFETs may have better performance than NFETs. To achieve NFETs and PFETs with balanced performance, many efforts have been tried. For example, one way is to adjust the threshold voltages of the NFETs and PFETs. However, adjusting the threshold voltages of transistors may affect their switching characteristics such as turn-on and/or turn-off behavior or noise margin. Another way is to reduce the channel width of the PFET or increase the channel width of NFETs such that the performance of NFET is comparable with that of PFET. However, scaling down the PFET may increase the complexity of fabrication, and scaling up the NFET may disadvantageously increase footprint.

In the present disclosure, the NFETs and PFETs are gate-all-around (GAA) transistors each including a number of channel members to serve as the channel and gate structure wrapping around the channel members. The transistors (NFETs and/or PFETs) in this present disclosure may include a partially oxidized topmost member so as to provide a reduced parasitic capacitance. A reduced parasitic capacitance may lead to a reduced resistance-capacitance (RC) delay and a reduced leakage, and thus a lower power consumption or boosted speed. In some embodiments, the channel members of the NFETs and PFETs may be treated to provide the desired performance without adjusting the threshold voltages or channel widths. For example, to obtain NFET and PFET with balanced performance, a topmost channel member of the PFET may be at least partially oxidized. In some other suitable applications, the concept of partially oxidizing the topmost channel member to reduce parasitic capacitance may also be implemented to form NFETs. Thus, transistors in the present disclosure and various circuits and dies including the transistors may have enhanced performance.

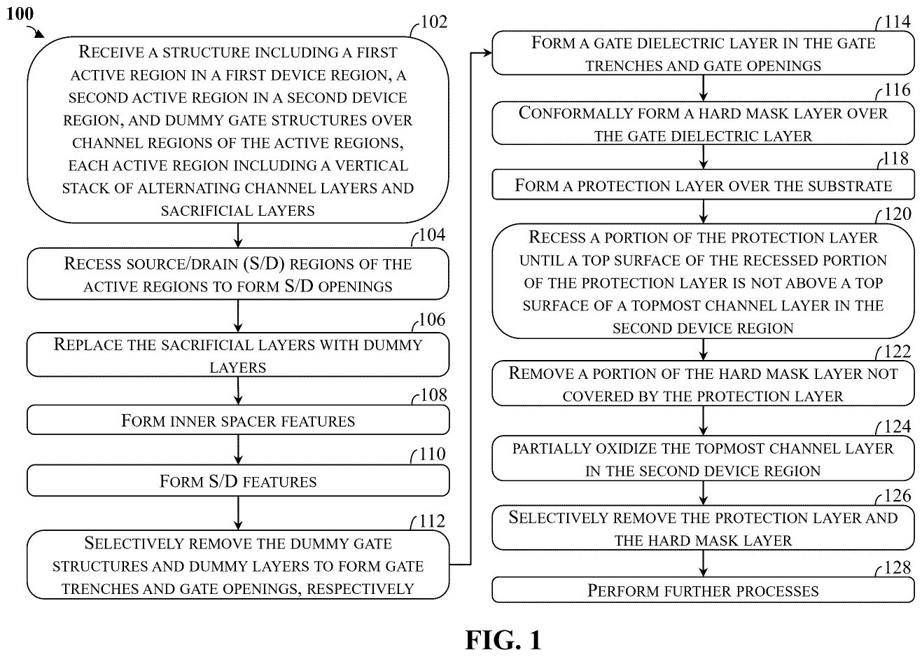

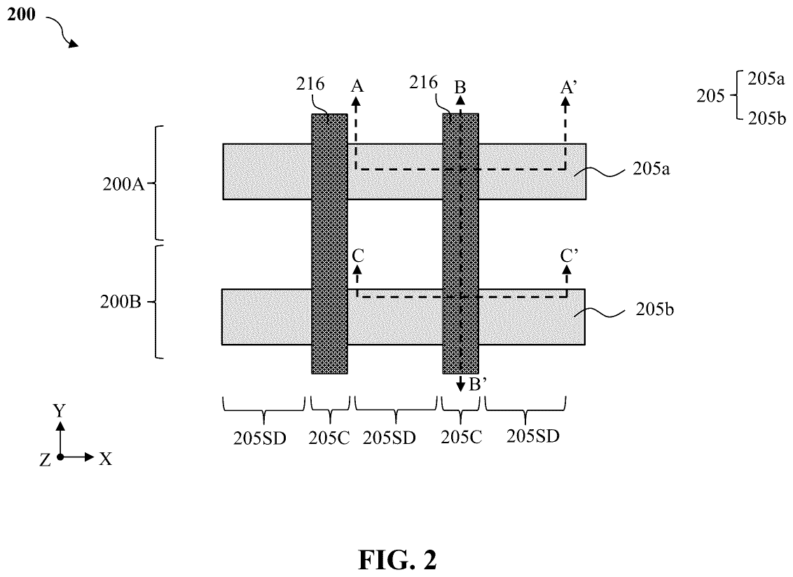

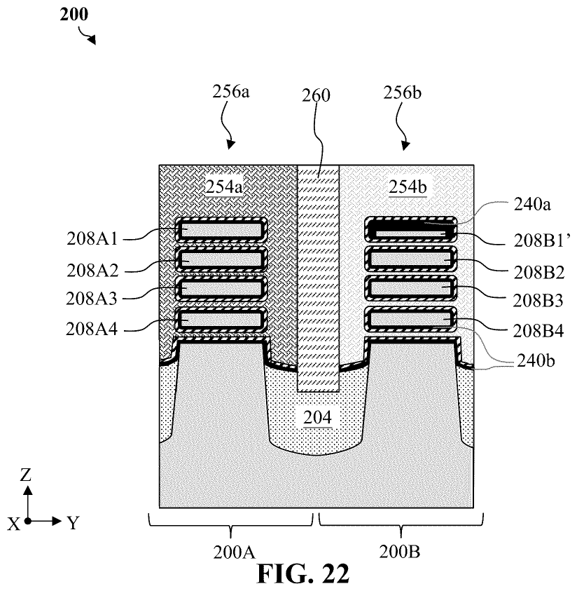

The various aspects of the present disclosure will now be described in more detail with reference to the figures. In that regard, FIG. 1 is a flowchart illustrating method 100 of forming a semiconductor structure 200 according to embodiments of the present disclosure. Method 100 is described below in conjunction with FIGS. 2-21B, which are fragmentary cross-sectional views or top views of a structure at different stages of fabrication according to embodiments of method 100. FIGS. 22-29 represent alternative embodiments or various aspects of the present disclosure.

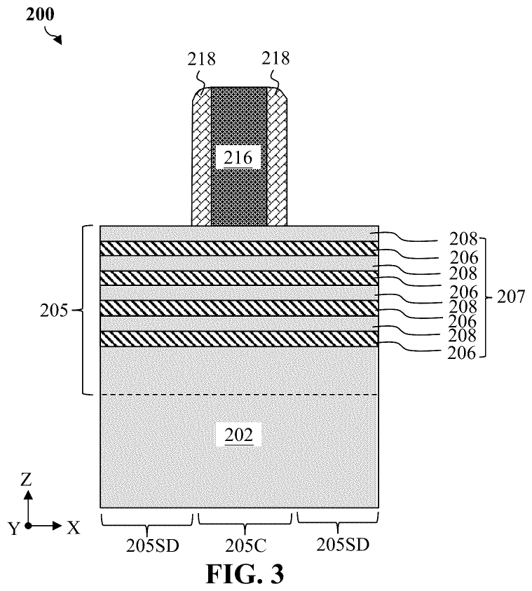

Referring to FIGS. 1 and 2-3, method 100 includes a block 102 where a structure 200 is received. FIG. 3 depicts a fragmentary cross-sectional view of the structure 200 taken along line A-A′ shown in FIG. 2. A fragmentary cross-sectional view of the structure 200 taken along line C-C′ shown in FIG. 2 is similar to FIG. 3 and is omitted for reason of simplicity. In this illustrated embodiment, the structure 200 includes a first device region 200A for forming N-type devices (e.g., N-type gate-all-around (GAA) transistors) and a second device region 200B for forming P-type devices (e.g., P-type GAA transistors). The structure 200 includes a substrate 202 (shown in FIG. 3). In an embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator substrate, or a germanium-on-insulator substrate, and includes a carrier, an insulator on the carrier, and a semiconductor layer on the insulator. The substrate 202 can include various doped regions configured according to design requirements of semiconductor structure 200. P-type doped regions may include p-type dopants, such as boron, indium, other p-type dopant, or combinations thereof. N-type doped regions may include n-type dopants, such as phosphorus, arsenic, other n-type dopant, or combinations thereof. In some implementations, the substrate 202 includes doped regions formed with a combination of p-type dopants and n-type dopants. The various doped regions can be formed directly on and/or in substrate 202, for example, providing a p-well structure, an n-well structure, a dual-well structure, a raised structure, or combinations thereof. An ion implantation process, a diffusion process, and/or other suitable doping process can be performed to form the various doped regions.

The structure 200 also includes multiple active regions (e.g., active regions 205a, 205b) protruding from the substrate 202. In the present embodiments, the active region 205a is formed in the first device region 200A (shown in FIG. 2) of the structure 200, and the active region 205b is formed in the second device region 200B of the structure 200. The active regions 205a and 205b may be separately or collectively referred to as active region(s) 205. Each of the active regions 205 extends lengthwise along the X direction and is divided into channel regions 205C and source/drain regions 205SD. Source/drain region(s) may refer to a source region or a drain region, individually or collectively dependent upon the context.

The active region 205 may be formed from a top portion of the substrate 202 and a vertical stack 207 (shown in FIG. 3) of alternating semiconductor layers 206 and 208 using a combination of lithography and etch steps. In the depicted embodiment, the vertical stack 207 of alternating semiconductor layers 206 and 208 includes a number of channel layers 208 interleaved by a number of sacrificial layers 206. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes. In this depicted example, each of the active regions 205 includes four sacrificial layers 206 interleaved by four channel layers 208. In some other examples, each of the active regions 205 may include a total of three to ten pairs of alternating sacrificial layers 206 and channel layers 208; of course, other configurations may also be applicable depending upon specific design requirements.

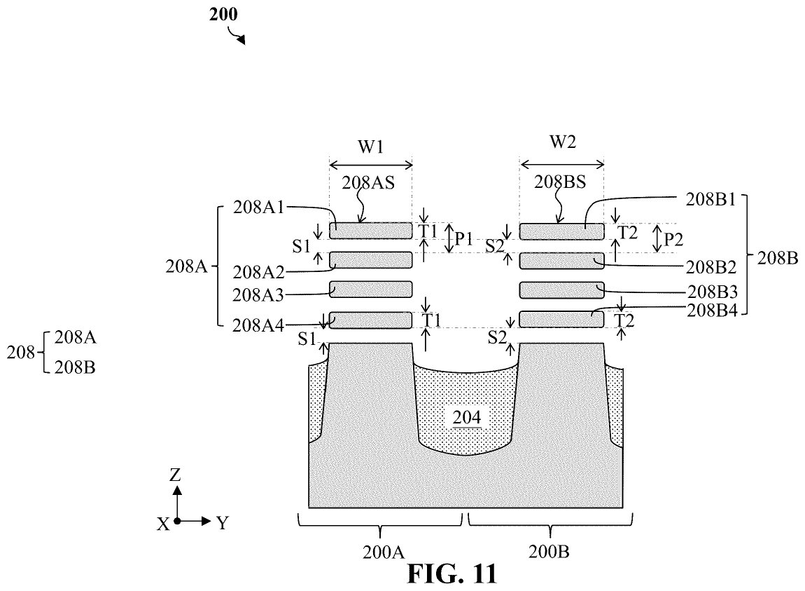

The structure 200 also includes an isolation feature 204 (shown in FIG. 11) formed over the substrate 202 to isolate two adjacent active regions 205. The isolation feature 204 may include a shallow trench isolation (STI) feature and thus may also be referred to as a STI feature. In some embodiments, the STI feature 204 may include silicon oxide, silicon oxynitride, fluorine-doped silicate glass (FSG), a low-k dielectric, combinations thereof, and/or other suitable materials. In some embodiments, a top surface of the STI feature 204 is lower than a top surface of the top portion of the substrate 202. The top surface of the STI feature 204 may be a curved (e.g., concave) surface having a lowest point near its middle.

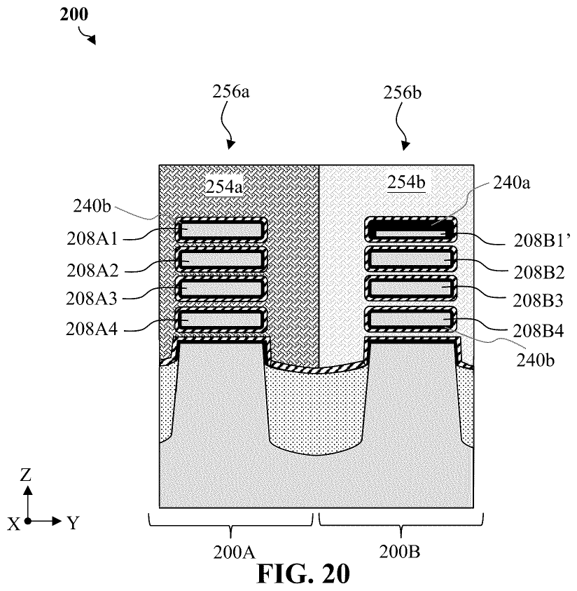

Still referring to FIGS. 2-3, the structure 200 also includes dummy gate structures 216 formed over channel regions 205C of the active regions 205. The channel regions 205C and the dummy gate structures 216 also define source/drain regions 205SD that are not vertically overlapped by the dummy gate structures 216. Each of the channel regions 205C is disposed between two source/drain regions 205SD along the X direction. Two dummy gate structures 216 are shown in FIG. 2 but the structure 200 may include other numbers of dummy gate structures. In this embodiment, a gate replacement process (or gate-last process) is adopted where the dummy gate structures 216 serve as placeholders for functional gate structures (e.g., functional gate structures 256a, 256b shown in FIG. 20). Other processes for forming the functional gate structures are possible. In the present embodiments, although not separately shown, each of the dummy gate structures 216 includes a dummy gate dielectric layer (e.g., silicon oxide) and a dummy gate electrode (e.g., polysilicon) disposed over the dummy gate dielectric layer. The structure 200 also includes gate spacers 218 extending along sidewalls of the dummy gate structures 216. In some embodiments, the gate spacers 218 may include silicon oxide, silicon oxycarbide, silicon carbonitride, silicon oxycarbonitride, silicon nitride, zirconium oxide, aluminum oxide, or a suitable dielectric material. The gate spacer 218 may be a single-layer structure or a multi-layer structure.

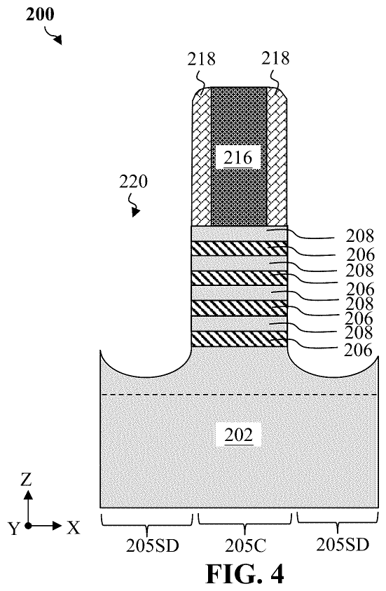

Referring to FIGS. 1 and 4, method 100 includes a block 104 where source/drain regions 205SD of the active regions 205 are recessed to form source/drain openings 220. FIG. 4 depicts a fragmentary cross-sectional view of the structure 200 taken along line A-A′ shown in FIG. 2. A fragmentary cross-sectional view of the structure 200 taken along line C-C′ shown in FIG. 2 is similar to FIG. 4 and is omitted for reason of simplicity. In some embodiments, the source/drain regions 205SD of the active region 205 that are not covered by the dummy gate structures 216 and the gate spacers 218 are anisotropically etched by a dry etch or a suitable etching process to form source/drain openings 220. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₁₄, and/or BCl₁₃), a bromine-containing gas (e.g., HBr and/or CHBr₃), an iodine-containing gas, other suitable gases and/or plasmas, and/or combinations thereof. The source/drain openings 220 extend through the stack 207 of channel layers 208 and sacrificial layers 206 and extend into the substrate 202. As illustrated by FIG. 4, sidewalls of the channel layers 208 and the sacrificial layers 206 are exposed in the source/drain openings 220.

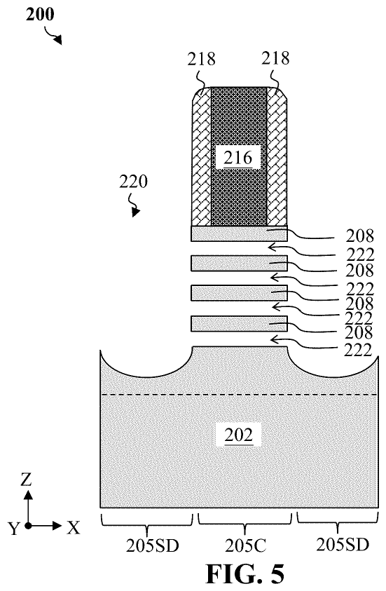

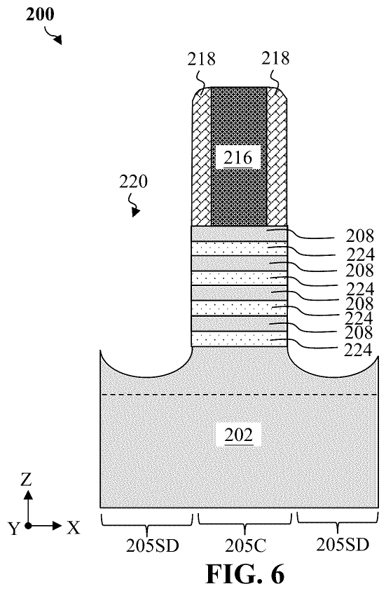

Referring to FIGS. 1 and 5-6, method 100 includes a block 106 where the sacrificial layers 206 are replaced with dummy layers 224. FIGS. 5 and 6 depict fragmentary cross-sectional views of the structure 200 taken along line A-A′ shown in FIG. 2. Fragmentary cross-sectional views of the structure 200 taken along line C-C′ shown in FIG. 2 is similar to FIGS. 4-5 and are omitted for reason of simplicity. With reference to FIG. 5, after the formation of the source/drain openings 220, the sacrificial layers 206 interleaving the channel layers 208 in the channel region 205C are selectively removed. The selective removal of the sacrificial layers 206 releases the channel layers 208 to form channel members 208 (“channel release process”). Depending on the design, the channel members 208 may take form of nanowires, nanosheets, or other nanostructures. The selective removal of the sacrificial layers 206 forms spaces 222 between and around adjacent channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

With reference to FIG. 6, after the selective removal of the sacrificial layers 206, in an example process, a dielectric material layer is deposited around the channel members 208 and over the source/drain openings 220. The dielectric material layer fills the spaces 222 among the channel members 208 and covers end sidewalls of the channel members 208. After the deposition of the dielectric material layer, an etching process is performed to selectively etch the dielectric material layer, thereby forming the dummy layers 224 interleaved by the channel members 208. The dummy layers 224 may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or atomic layer deposition (ALD) or other suitable methods. In an embodiment, the dummy layers 224 include silicon oxide.

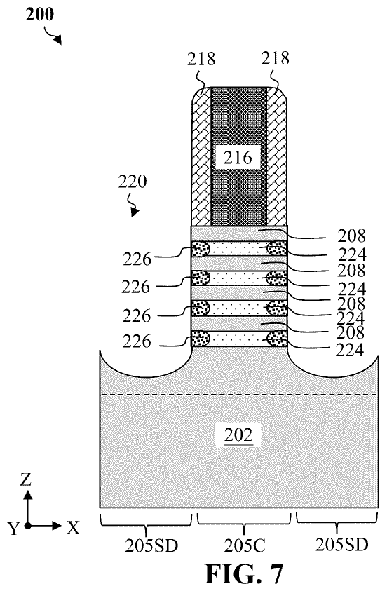

Referring to FIGS. 1 and 7, method 100 includes a block 108 where inner spacer features 226 are formed. After forming the dummy layers 224, an etching process is performed to selectively recess the dummy layers 224 to form inner spacer recesses (now filled by inner spacer features 226). The etching process selectively and partially recesses the dummy layers 224 to form inner spacer recesses, while the exposed channel members 208 are not significantly etched. In an embodiment where the channel members 208 consist essentially of silicon (Si) and the dummy layers 224 are formed of silicon oxide, the selective recess of the dummy layer 224 may be performed using a selective wet etch process or a selective dry etch process. The extent at which the dummy layers 224 are recessed is controlled by duration of the etching process. In an alternative embodiment, the etch back of the dielectric material layer for forming the dummy layers 224 and the selective and partial recess of the dummy layers 224 are conducted by performing a same etching process. Inner spacer features 226 are then formed in the inner spacer recesses. In an example process, after the formation of the inner spacer recesses, an inner spacer material layer (not shown) is deposited over the structure 200, including in the inner spacer recesses. The deposited inner spacer material layer is then etched back to remove excessive inner spacer material layer, thereby forming the inner spacer features 226. The etch back process at block 108 may be a dry etching process that is similar to the dry etching process used in the formation of the source/drain openings 220. The inner spacer features 226 track the shapes of the corresponding inner spacer recesses. The inner spacer material layer may include silicon oxide, silicon nitride, silicon oxycarbide, silicon oxycarbonitride, silicon carbonitride, metal nitride, or a suitable dielectric material.

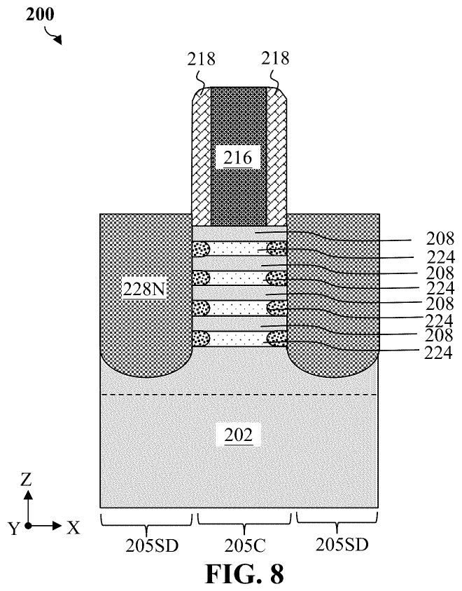

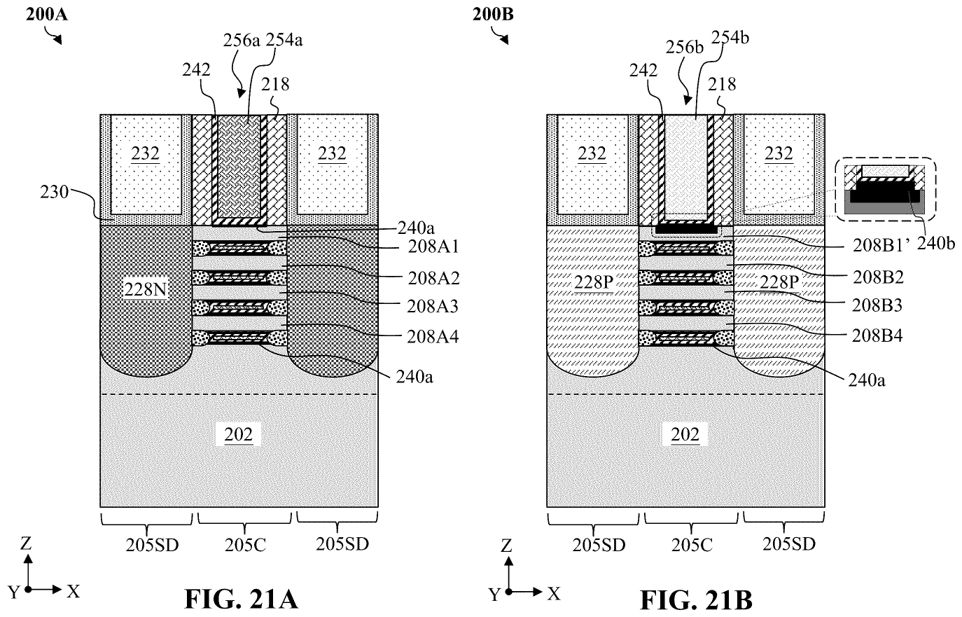

Referring to FIGS. 1 and 8, method 100 includes a block 110 where source/drain features (e.g., source/drain features 228N and 228P) are formed adjacent to the channel regions 205C. The source/drain features are formed in and/or over source/drain regions 205SD and coupled to the channel layers 208 in the channel regions 205C. In the present embodiments, N-type source/drain features 228N are formed in the first device region 200A, and P-type source/drain features 228P (shown in FIG. 21B) are formed in the second device region 200B. Exemplary N-type source/drain features 228N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary P-type source/drain features 228P may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In various embodiments, top surfaces of the source/drain features 228N and/or 228P may be non-planar or curved surfaces that curve inward or outward (e.g., concave or convex). In some embodiments, top surfaces of the source/drain features 228N and/or 228P are not coplanar with a top surface of the topmost channel layer 208 of the channel layers 208.

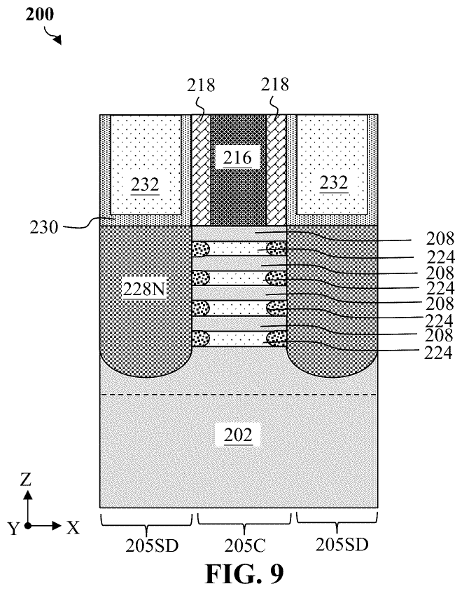

Referring to FIGS. 1 and 9-11, method 100 includes a block 112 where the dummy gate structures 216 are selectively removed to form gate trenches 234 and the dummy layers 224 are selectively removed to form gate openings 236. With reference to FIG. 9, after forming the source/drain features 228N and 228P, a contact etch stop layer (CESL) 230 and an interlayer dielectric (ILD) layer 232 are formed over the structure 200. The CESL 230 is configured to protect the various underlying components during subsequent fabrication processes and may include silicon nitride, silicon oxynitride, and/or other suitable materials and may be formed by atomic layer deposition (ALD), chemical vapor deposition (CVD), plasma-enhanced chemical vapor deposition (PECVD) process and/or other suitable deposition or oxidation processes. As shown in FIG. 9, the CESL 230 may be formed on top surfaces of the source/drain features (e.g., the N-type source/drain features 228N) and sidewalls of the gate spacers 218. The ILD layer 232 is deposited by a CVD process, a PECVD process or other suitable deposition technique over the structure 200 after the depositing of the CESL 230. The ILD layer 232 may include silicon oxide, a low-k dielectric material, tetraethyl orthosilicate (TEOS), doped silicon oxide (e.g., BPSG, FSG, PSG, BSG, etc.), other suitable dielectric materials, or combinations thereof. One or more chemical mechanical planarization (CMP) processes may be performed to planarize the top surface of the structure 200 to expose dummy gate electrode of the dummy gate structures 216.

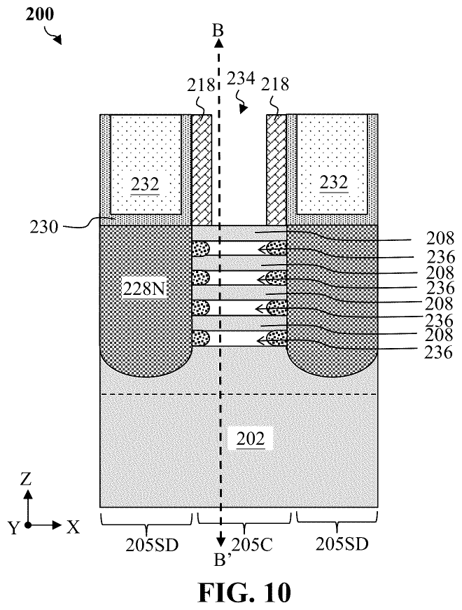

With reference to FIG. 10, the dummy gate structures 216 are selectively removed to form gate trenches 234 over the channel regions 205C. Etching process for selectively removing the dummy gate structures 216 may include any suitable process, such as a dry etching process, a wet etching process, or combinations thereof. After the removal of the dummy gate structures 216, the dummy layers 224 are selectively removed to form gate openings 236. The selective removal of the dummy layers 224 may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH4F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the selective wet etching includes an APM etch (e.g., ammonia hydroxide-hydrogen peroxide-water mixture).

FIG. 11 depicts a cross-sectional view of the structure 200 taken along line B-B′ shown in FIG. 2 and FIG. 10. For ease of description, the channel members 208 in the first device region 200A are referred to as channel members 208A, the channel members 208 in the second device region 200B are referred to as channel members 208B. More specifically, in this depicted example, the channel members 208A include a topmost channel member 208A1, a first middle channel member 208A2 under the topmost channel member 208A1, a second middle channel member 208A3 under the first middle channel member 208A2, and a bottommost channel member 208A4. The channel members 208A1, 208A2, 208A3, and 208A4l may be collectively or individually referred to as channel member(s) 208A. The channel members 208B1, 208B2, 208B3, and 208B4 may be collectively or individually referred to as channel member(s) 208B. In some embodiments, the channel member 208A and the channel member 208B may have same dimensional configurations. For example, the channel member 208A have a width W1 substantially equal to the width W2 of the channel member 208B, a thickness T1 substantially equal to the thickness T2 of the channel member 208B. The channel members 208A have a vertical pitch P1 (either center-to-center pitch or edge-to-edge pitch) substantially equal to the vertical pitch P2 of the channel members 208B. Two adjacent layers of the channel members 208A are separated by a spacing S1, two adjacent layers of the channel members 208B are separated by a spacing S2, and S2 may be substantially equal to the spacing S1. A top surface 208AS of the topmost channel member 208A1 is substantially coplanar with a top surface 208BS of the topmost channel members 208B1. In some other implementations, the channel members 208A in the first device region 200A and the channel members 208B in the second device region 200B may have same pitch (i.e., P1=P2), same spacing (i.e., S1=S2), same thickness (i.e., T1=T2), but different widths (i.e., the width W1 is different from the width W2) to further flexibly adjust the performances of P-type transistors and N-type transistors.

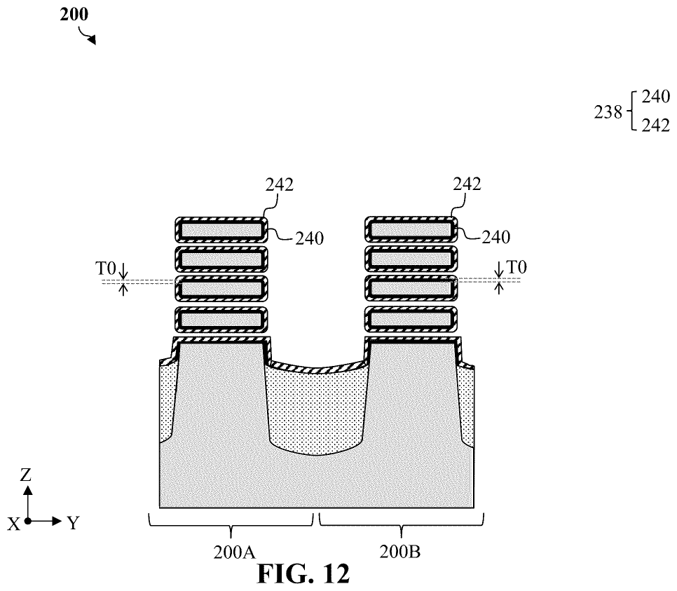

Referring to FIGS. 1 and 12, method 100 includes a block 114 where a gate dielectric layer 238 is formed over the structure 200, including in the gate trenches 234 and gate openings 236. In some embodiments, the gate dielectric layer 238 is a multi-layer structure that includes an interfacial layer 240 and a high-K dielectric layer 242 over the interfacial layer 240. In this illustrated embodiment, the interfacial layer 240 is formed by thermal oxidization and may include silicon oxide. That is, the interfacial layer 240 is only formed along exposed surfaces of the semiconductor features (e.g., the top portion of the substrate 202 and the channel members 208A and 208B). The interfacial layer 240 may have a generally uniform thickness T0. In some embodiments (e.g., embodiments represented by FIG. 22), the interfacial layer 240 may be conformally deposited over the substrate 202, including in the gate trenches 234 and the gate openings 236 and on the STI feature 204 using a deposition process such as ALD or CVD.

The high-K dielectric layer 242 is then conformally deposited over the structure 200 by performing a deposition process (e.g., CVD, ALD) to have a generally uniform thickness over the top surface of the structure 200 to partially fill the gate trenches 234 and the gate openings 236. The term “conformally” may be used herein for ease of description of a layer having substantially uniform thickness over various regions. The high-K dielectric layer 242 may include dielectric materials having a high dielectric constant, for example, greater than a dielectric constant of silicon oxide. Exemplary high-K dielectric materials include hafnium, zirconium, tantalum, titanium, oxygen, nitrogen, other suitable constituent, or combinations thereof. In some implementations, the high-K dielectric layer 242 may include a high-K dielectric material including, for example, HfO₂, HfSiO, HfSiON, HfTaO, HfTiO, HfZrO, ZrO₂, TiO₂, Ta₂O₅, other suitable high-K dielectric material, or combinations thereof.

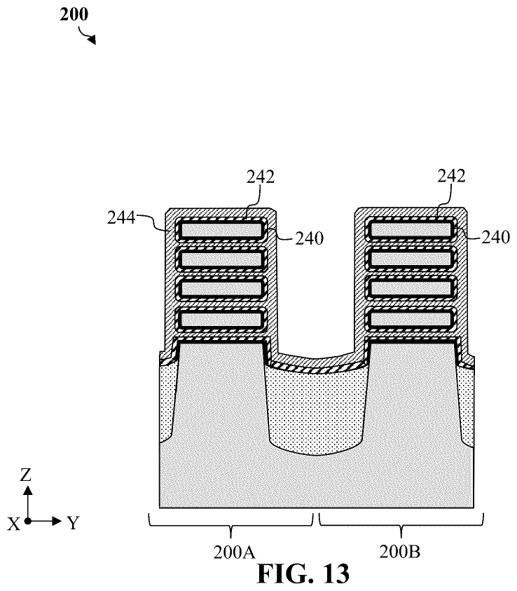

Referring now to FIGS. 1 and 13, method 100 includes a block 116 where a hard mask layer 244 is conformally formed over the substrate 202. The hard mask layer 244 is conformally deposited over the substrate 202 to have a generally uniform thickness over the top surface of the structure 200 by any of the processes described herein, such as ALD, CVD, physical vapor deposition (PVD), other suitable process, or combinations thereof. A thickness of the hard mask layer 244 is configured to fill any remaining portion of the gate openings 236 between the adjacent channel members 208 in the first and second device regions 200A and 200B. In the present embodiments, after the depositing of the hard mask layer 244, the gate openings 236 are substantially filled and the gate trenches 234 are still partially filled. The hard mask layer 244 includes a material that achieves high etching selectivity between the hard mask layer 244 and high-K dielectric layer 242 during an etching process. For example, the hard mask layer 244 can be selectively etched with minimal (to no) etching of the high-K dielectric layer 242 in an etching process, which can be a dry etching process or a wet etching process. In some embodiments, the etching selectivity is 10:1 or more. In other words, the etching process etches the hard mask layer 244 at a rate that is at least 10 times greater than a rate at which it etches the high-K dielectric layer 242. In some embodiments, the hard mask layer 244 includes aluminum oxide or alumina, silicon oxide, silicon nitride, lanthanum oxide, silicon (such as polysilicon), silicon carbonitride, silicon oxycarbonitride, aluminum nitride, aluminum oxynitride, a combination thereof, or other suitable materials.

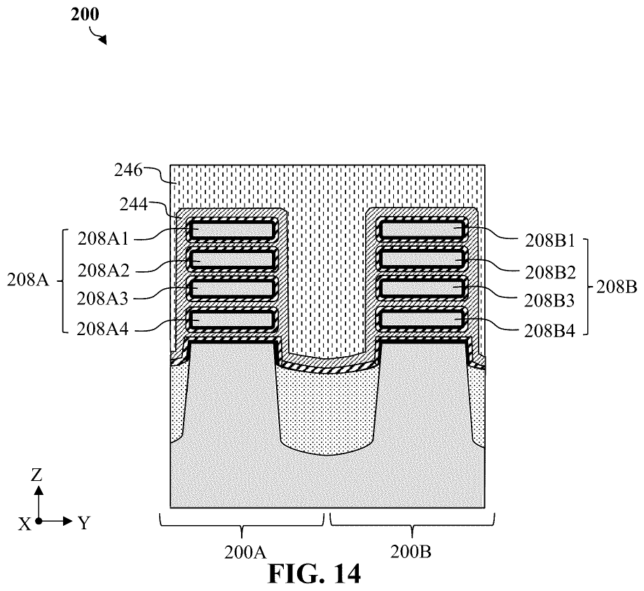

Referring now to FIGS. 1 and 14, method 100 includes a block 118 where a protection layer 246 is formed over the substrate 202. In an embodiment, the protection layer 246 includes a bottom antireflective coating (BARC) material that provides a platform for photoresist coating and photoresist patterning. In an embodiment, the protection layer 246 is formed by spin coating a BARC material over the substrate 202 and in the gate trenches 234, and baking the BARC material to cause cross-linking within the BARC material. A top surface of the protection layer 246 is above a top surface of the hard mask layer 244.

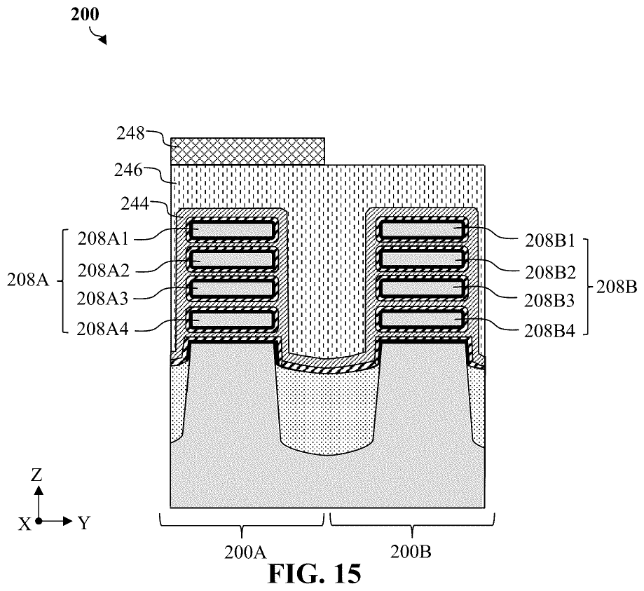

Referring now to FIGS. 1 and 15-16, method 100 includes a block 120 where a portion of the protection layer 246 in the second device region 200B is recessed. After forming the protection layer 246, with reference to FIG. 15, a patterned photoresist layer 248 is formed over the protection layer 246. In an example process, a photoresist layer may be blanketly deposited over the structure 200, including over the protection layer 246 in the first device region 200A and the second device region 200B. The photoresist layer is then exposed to radiation going through or reflected from a mask, baked in a post-bake process, and developed in a developer solution to form the patterned photoresist layer 248, as represented in FIG. 15. In this illustrated embodiment, the patterned photoresist layer 248 is formed in the first device region 200A and is not formed in the second device region 200B.

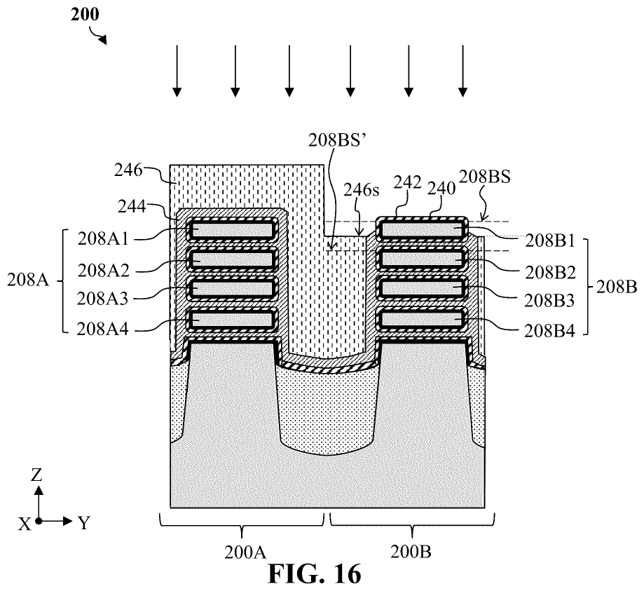

With reference to FIG. 16, an etching process is performed to recess the protection layer 246 while using the patterned photoresist layer 248 as an etch mask. The etching process may include an isotropic etching process or anisotropic etching process and may be a dry etch. In some embodiments, the extent at which the protection layer 246 is recessed may be controlled by the duration of the etching process. After recessing the protection layer 246 in the second device region 200B, the patterned photoresist layer 248 may be selectively removed. In some cases, the patterned photoresist layer 248 may be removed during the etching process that is performed to recess the protection layer 246.

In embodiments represented by FIG. 16, the recessed protection layer 246 in the second region 200B has a top surface 246s. The top surface 246s may be at a level that is in a range between the top surface 208BS of the topmost channel member 208B1 and a top surface 208BS′ of the first middle channel member 208B1 to facilitate the treatment to the topmost channel member 208B1 of the channel members 208B in the second device region 200B. That is, the top surface 246s may be coplanar with the top surface 208BS, below the top surface 208BS and above the top surface 208BS′, or coplanar with the top surface 208BS′ such that the treatment to the topmost channel member 208B1 would not substantially affect the channel member (e.g., the first middle channel member 208B1) disposed immediately under the topmost channel member 208B1. In this illustrated embodiment, the top surface 246s is coplanar with a bottom surface of the topmost channel member 208B1 of the channel members 208B in the second device region 200B.

Still referring to FIGS. 1 and 16, method 100 includes a block 122 where an etching process is performed to selectively remove a portion of the hard mask layer 244 exposed by the recessed protection layer 246. After recessing the protection layer 246, while using the recessed protection layer 246 as an etch mask, an etching process is performed to selectively etch away the portion of the hard mask layer 244 not covered by the recessed protection layer 246, thereby exposing a portion of the gate dielectric layer 238 (e.g., high-K dielectric layer 242) in the second device region 200B and in contact with the topmost channel member 208B1. The etching process may be a dry etch process, a wet etch process, or a suitable etch process.

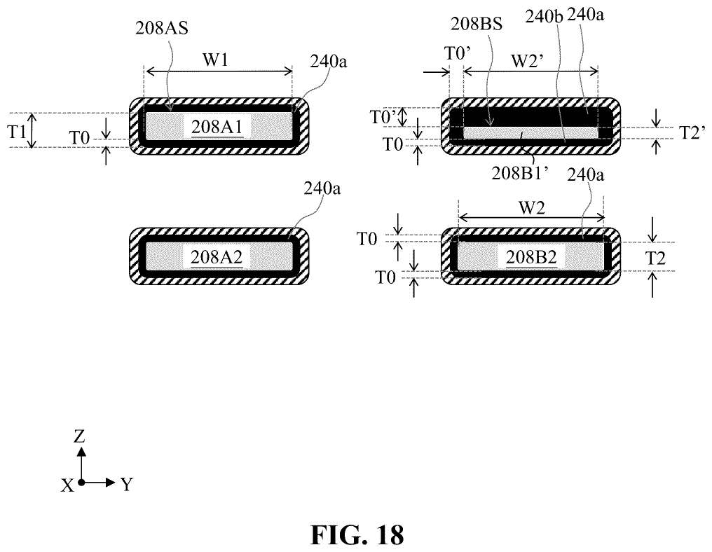

Referring now to FIGS. 1 and 17-18, method 100 includes a block 124 where the topmost channel member 208B1 in the second device region 200B is partially oxidized. FIG. 18 depicts a fragmentary and enlarged portion (e.g., topmost channel members 208A1, 208B1 and first middle channel members 208A2, 208B2) of the structure 200. After exposing a portion of the gate dielectric layer 238 (e.g., high-K dielectric layer 242) in the second device region 200B, a directional (e.g., anisotropic) plasma treatment process 250 is performed to oxidize at least a portion of the topmost channel member 208B1 from top to bottom, thereby increasing a thickness of the portion of the interfacial layer 240 that is disposed adjacent to and on the topmost channel member 208B1. In some embodiments, the directional plasma treatment 250 may include use of a combination of a nitrogen (N₂) plasma and an oxygen (O₂) plasma.

After the performing of the directional plasma treatment 250, for ease of description, the portion of the interfacial layer 240 having an increased thickness (e.g., T0′ shown in FIG. 18) may be referred to as the interfacial layer 240a, and the portion of the interfacial layer 240 having the substantially unchanged thickness T0 may be referred to as the interfacial layer 240b. For example, the portion of the interfacial layer 240 disposed under the topmost channel member 208B1 in the second device region 200B and the portion of the interfacial layer 240 in the first device region 200A are protected by the hard mask layer 244 and are thus not thickened and are referred to as the interfacial layer 240b. Thus, the interfacial layer in the second device region 200B now has a non-uniform thickness (e.g., T0 or T0'). In an embodiment, a ratio of the thickness T0′ to the thickness T0 may be greater than about 1.5. If the ratio is less than 1.5, the extent at which the topmost channel member 208B1 being oxidized may not be enough to adjust the performance of the transistors formed in the second device region 200B. In some embodiments, after performing the directional plasma treatment 250, a composition of the topmost channel member 208B1 is different than other channel members (e.g., the channel members 208A1-208A4 and 208B2-208B4). For example, an oxygen concentration of the topmost channel member 208B1 is greater than an oxygen concentration of other channel members (e.g., the channel members 208A1-208A4 and 208B2-208B4). The topmost channel member 208B1 after being partially oxidized may be referred to as the topmost channel member 208B1′. Due to the partially oxidization, the topmost channel member 208B1′ now has a thickness T2′ less than the thickness T2. In an embodiment, a ratio of the thickness T2′ to the thickness T2 is less than 0.8 such that the performance of the transistors formed in the second device region 200B may be adjusted. The topmost channel member 208B1′ now has a width W2′ less than the width W2. In an embodiment, the width W1 is equal to the width W2 and is greater than the width W2′. In another embodiment, the width W1 is greater than the width W2 and the width W2′. In some other implementations, the width W1 is less than the width W2, and may be less than, equal to, or greater than the width W2′. In an example, the width W2 is in a range between about 3 nm and about 6 nm, and the width W2′ is in a range between about 0 and about 4 nm. Since the topmost channel member 208B1′ is oxidized from top to bottom, a top surface 208BS of the topmost channel member 208B1′ is now lower than the top surface 208AS of the topmost channel member 208A1, while the bottom surface of the topmost channel member 208B1′ is still coplanar with the bottom surface of the topmost channel member 208A1. While the spacing S2 between topmost channel member 208B1′ and the first middle channel member 208B2 is unchanged (e.g., S2), the pitch P2 therebetween (e.g., a distance between the top surface 208BS of the topmost channel member 208B1′ and the top surface 208BS of first middle channel member 208B2) is decreased. That is, the vertically pitch of the channel members 208B is now non-uniform.

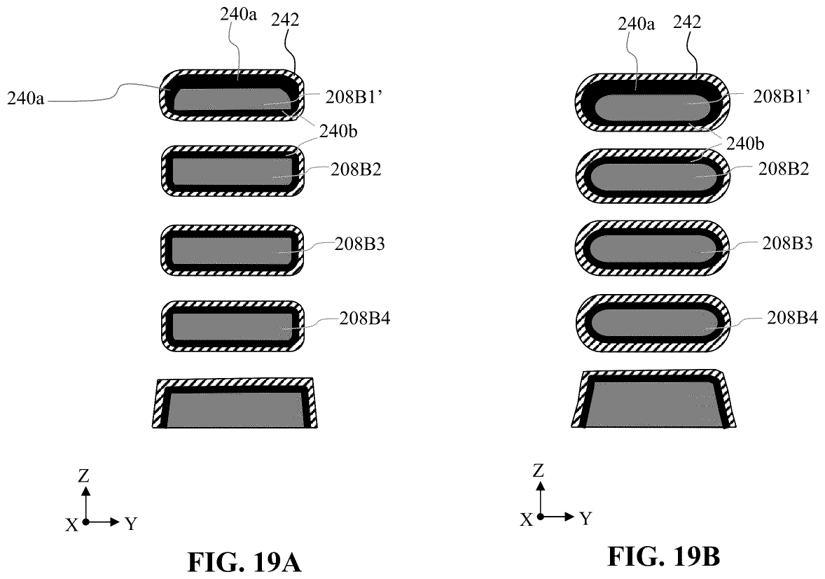

FIG. 19A and FIG. 19B each depicts a fragmentary cross-sectional view of the channel members 208B in the second device region 200B. The channel members 208B depicted in FIG. 19A and FIG. 19B are similar to the channel members 208B depicted in FIG. 18B, and one of the differences includes the different profiles of the channel members 208B. More specifically, the topmost channel member 208B1′ shown in FIG. 18 resembles a rectangular with rounded corners, while the topmost channel member 208B1′ shown in FIG. 19A resembles a trapezoid with rounded corners. The profile may be formed due to various parameters associated with the plasma treatment process 250, may be facet-dependent, or may be associated with different channel widths. In this illustrated embodiment, the portion of the interfacial layer 240a formed on the top surface 208BS of the topmost channel member 208B1′ may have a uniform thickness, while the portion of the interfacial layer 240a formed laterally adjacent to the topmost channel member 208B1′ may have a non-uniform thickness that gradually increases from bottom to top. In the above embodiments, the channel member 208B prior to the performing of the plasma treatment process 250 resembles a rectangular with rounded corners, in embodiment represented by FIG. 19B, the channel member 208B prior to the performing of the plasma treatment process 250 may resemble a spherocylinder. This profile may be caused by another mechanism (e.g., a mechanism that does not include forming the dummy layers 224) of releasing the channel layers 208 as channel members. The dimensional configurations of the channel members 208B in FIG. 19A and FIG. 19B are substantially the same as those of the channel members 208B in FIG. 18, and repeated description is omitted for reason of simplicity.

Referring now to FIGS. 1 and 20, method 100 includes a block 126 where the hard mask layer 244 and the recessed protection layer 246 are selectively removed. After performing the plasma treatment process 250, one or more etching processes are performed to selectively remove the protection layer 246 and the hard mask layer 244 without substantially etching the high-K dielectric layer 242. In some embodiments, during the performing of the plasma treatment process 250, the protection layer 246 may be slightly etched.

Referring now to FIGS. 1, 20 and 21A-21B, method 100 includes a block 128 where further processes are performed. Such further processes may include forming a gate electrode 254a over the gate dielectric layer 238 in the first device region 200A and a gate electrode 254b over the gate dielectric layer 238 in the second device region 200B to form metal gate structures 256a and 256b. The gate electrode 254a/254b may be a multi-layer structure that includes at least one work function layer and a metal fill layer. By way of example, the at least one work function layer may include titanium nitride (TiN), titanium aluminum (TiAl), titanium aluminum nitride (TiAIN), tantalum nitride (TaN), tantalum aluminum (TaAl), tantalum aluminum nitride (TaAIN), tantalum aluminum carbide (TaAIC), tantalum carbonitride (TaCN), or tantalum carbide (TaC). The gate electrode 254a formed in the first device region 200A may include at least an N-type work function layer. The N-type work function layer may include titanium-aluminum based metal, such as titanium aluminum carbon (TiAIC) or titanium aluminum (TiAl). The gate electrode 254b formed in the second device region 200B may include at least a P-type work function layer. The P-type work function layer may include titanium nitride (TiN), tungsten carbonitride (WCN), tantalum nitride (TaN), or molybdenum nitride (MoN). The gate electrode 254a/254b may also include a metal fill layer including aluminum (Al), tungsten (W), nickel (Ni), titanium (Ti), ruthenium (Ru), cobalt (Co), platinum (Pt), tantalum silicon nitride (TaSiN), copper (Cu), other refractory metals, or other suitable metal materials or a combination thereof. In various embodiments, the gate electrode 254a/254b may be formed by ALD, PVD, CVD, e-beam evaporation, or other suitable process. In various embodiments, a planarization process, such as a chemical mechanical polishing (CMP) process, may be performed to remove excess materials over the ILD layer 232 to provide a substantially planar top surface and facilitate the performing of further processes. FIG. 21A depicts a cross-sectional view of the structure 200 taken along line A-A′ (e.g., the first device region 200A), FIG. 21B depicts a cross-sectional view of the structure 200 taken along line C-C′ (e.g., the second device region 200B). As depicted in FIG. 21B, the interfacial layer 240b formed over the topmost channel member 208B1′ is thicker than the interfacial layer 240a. As a result of the partially oxidization, the topmost channel member 208B1′ has a non-uniform thickness when viewed in a X-direction cross-sectional view, as represented by FIG. 21B.

FIG. 22 depicts an alternative embodiment, according to according to various aspects of the disclosure. In this alternative embodiment, a gate isolation feature 260 is formed to provide isolation between the metal gate structures 256a and 256b. The gate isolation feature 260 may be formed before or after the formation of the metal gate structures 256a and 256b. In this illustrated embodiment, the gate isolation feature 260 extends into the STI feature 204. In other implementations, the gate isolation feature 260 may stop on the STI feature 204. The gate isolation feature 260 may be formed of any suitable dielectric materials and may be a single-layer structure or a multi-layer structure. In embodiments described above, the interfacial layer 240 is initially formed by thermal oxidization. In other implementations, the interfacial layer 240 may be conformally deposited over the entire structure 200, including on the STI feature 204. As represented by FIG. 22, after performing the plasma treatment process 250, a portion of the interfacial layer 240b is on the STI feature 204.

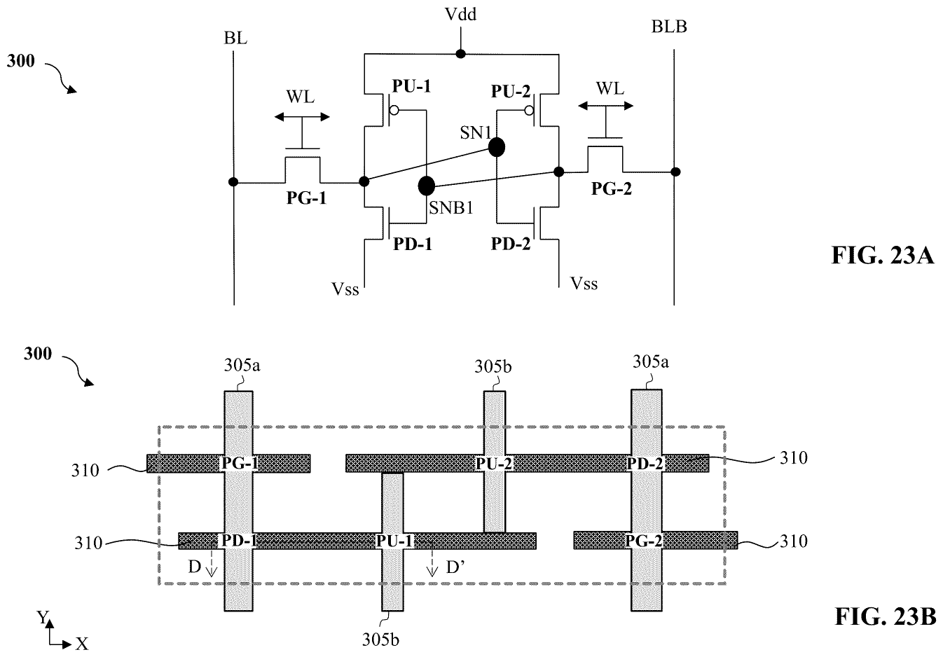

The method 100 may be applied to form an IC structure with improved performance (e.g., enhance speed, reduced power consumption, or reduced performance gap between NFETs and PFETs). With reference to FIGS. 23A-23B, the IC structure includes at least an array of memory cells. The array may include static random-access memory (SRAM) cells, dynamic random-access memory (DRAM) cells, non-volatile random-access memory (NVRAM) cells, flash memory cells, other suitable memory cells, or combinations thereof. In an embodiment, the array includes a number of SRAM cells 300, which generally provide memory or storage capable of retaining data when power is applied. In the present embodiments, each SRAM cell 300 includes one or more GAA transistors described above.

FIG. 23A illustrates an exemplary circuit schematic for a single-port SRAM cell (e.g., 1-bit SRAM cell) 300. The single-port SRAM cell 300 includes pull-up transistors PU-1, PU-2; pull-down transistors PD-1, PD-2; and pass-gate transistors PG-1, PG-2. As show in the circuit diagram, transistors PU-1 and PU-2 are P-type transistors, and transistors PG-1, PG-2, PD-1, and PD-2 are N-type transistors. The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a first data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to power voltage Vdd, and the sources of the pull-down transistors PD-1 and PD-2 are coupled to a voltage Vss, which may be an electrical ground in some embodiments. The first storage node SN1 of the first data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL.

FIG. 23B illustrates a fragmentary layout of the SRAM cell 300. The SRAM cell 300 includes P-type three-dimensional fin-like active regions 305a (hereafter referred to as P-type fins 305a) each disposed in a P-type doped region and N-type three-dimensional fin-like active regions 305b (hereafter referred to as N-type fins 305b) each disposed in an N-type doped region. The P-type fins 305a may be similar to the active regions 205a after the channel release process, and the N-type fins 305b may be similar to the active regions 205b after the channel release process. The SRAM cell 300 includes gate structures 310, which may be similar to the gate structures 256a and/or 256b, oriented lengthwise along the X direction and disposed over the P-type fins 305a and/or the N-type fins 305b to form various transistors such as pull-down transistors PD-1 and PD-2, pull-up transistors PU-1 and PU-2, and pass-gate transistors PG-1 and PG-2. A cross-sectional view of the SRAM cell 300 taken along line D-D′ shown in FIG. 23B may be substantially the same as the structure 200 represented by FIG. 20. By forming pull-up transistors PU-1 and PU-2 with the partially oxidized topmost channel member 208B1′, reduced performance gap between N-type GAA transistors and P-type GAA transistors can be achieved. Also, parasitic capacitance of the SRAM cell 300 may be reduced, and balanced performance of the SRAM cell 300 and IC structure may be improved.

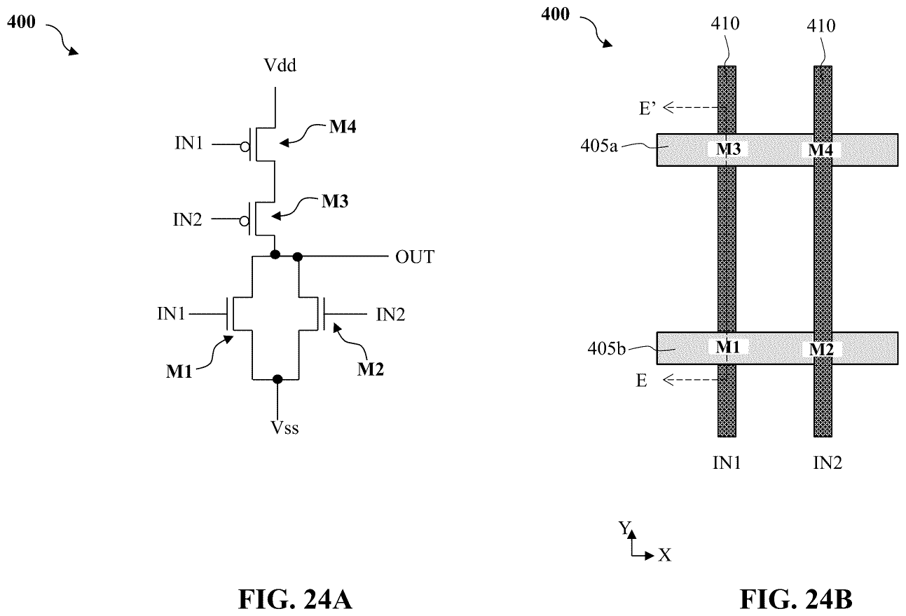

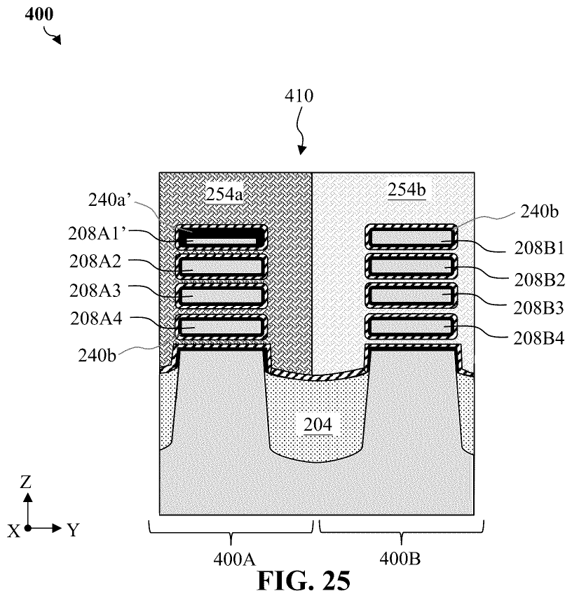

In the above embodiments, the topmost channel member 208B1 in the second device region 200B for forming P-type transistors are partially oxidized. In some other implementations, the topmost channel member 208A1 in the first device region 200A for forming N-type transistors are partially oxidized to enhance the performance of other IC structures. For example, in another application, with reference to FIGS. 24A-24B and 25, the IC structure includes at least an array of standard logic (STD) cells configured to provide various standard logic devices, such as inverter, AND, NAND, OR, XOR, NOR, other suitable devices, or combinations thereof. In the illustrated embodiments, standard logic (STD) cells include a number of NOR logic gates that includes N-type transistors with the partially oxidized topmost channel member 208A1 in the first device region 200A.

FIG. 24A illustrates an exemplary circuit schematic for a NOR logic gate 400. The NOR logic gate 400 includes two NFETs (e.g., M1 and M2) and two PFETs (e.g., M3 and M4). The two NFETs (e.g., M1 and M2) are connected in parallel, and the two PFETs (e.g., M3 and M4) are connected in serial and are also connected with the two NFETs in serial as illustrated in FIG. 24 to form the NOR logic gate 400. The NFET M1 and the PFET M4 are configured to receive a first input signal IN1, and the NFET M2 and the PFET M3 are configured to receive a second input signal IN2. The NOR logic gate 400 provides an output signal OUT in response to the received first input signal IN1 and the second input signal IN2.

FIG. 24B illustrates a fragmentary layout of the NOR logic gate 400. The NOR logic gate 400 includes active regions 405a-405b and gate structures 410 (similar to the gate structures 256a and/or 256b). The gate structures 410 are oriented lengthwise along the Y direction and disposed over the active regions 405a-405b to form various transistors such as the two NFETs M1 and M2 and two PFETs M3 and M4. A path is defined as a route to distribute signal in a circuit. A critical path is the place that mainly dominates the circuit speed (or signal distribution speed) that is dependent on different circuit applications. If the circuit speed is varied with transistors'performance significantly, then the path will be referred to as critical path; if the circuit speed is not substantially associated with transistors'performance, then the path will be referred to as a non-critical path. For the NOR logic gate 400, the two PFETs M3 and M4 are in a critical path, and the two NFETs M1 and M2 are in a non-critical path. It is beneficial to make the critical path and the non-critical path have different configurations during field operations to reduce power consumption while maintaining satisfactory circuit speed. In this illustrated implementation, the NFETs in the non-critical path are configurated to have the partially oxidized topmost channel member to achieve a lower power consumption. A cross-sectional view of the NOR logic gate 400 taken along line E-E′ is shown in FIG. 25.

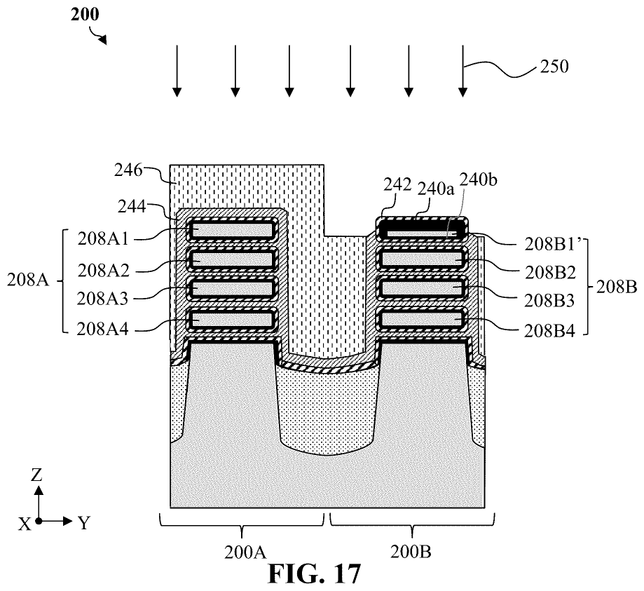

With reference to FIG. 25, the NOR logic gate 400 includes a first device region 400A for forming NFETs (e.g., M1 and M2) and a second device region 400B for forming PFETs (e.g., M3 and M4). In an exemplary process, operations in blocks 102-118 of method 100 described above with reference to FIGS. 1-14 are performed to form the channel members 208A in the first device region 400A and channel members 208B in the second device region 400B. Then, different from the embodiment described above with reference to FIGS. 15-19B where the topmost channel member 208B1 is partially oxidized to form the topmost channel member 208B1′ and the thickened interfacial layer 240a, in this illustrated example represented by FIG. 25, the topmost channel member 208A1 is partially oxidized to form a topmost channel member 208A1′ and a thickened interfacial layer 240a. For example, a patterned photoresist layer may be formed over the second device region 400B while exposing the first device region 400A, and then, operations in blocks 120-124 of method 100 are performed to recess the portion of the protection layer 246 in the first device region 400A, remove the hard mask layer 244 not covered by the recessed protection layer 246, and partially oxidize the topmost channel member 208A1 by performing the plasma treatment process 250. The relationship between the topmost channel member 208A1′ and the interfacial layer 240a′ is substantially the same as the relationship between the topmost channel member 208B1′ and the interfacial layer 240a described above with references to FIGS. 17-19B, and the relationship between the topmost channel member 208A1′ and other channel members (e.g., the topmost channel member 208B1, the first middle channel member 208A2) is substantially the same as the relationship between the topmost channel member 208B1′ and other channel members described above with references to FIGS. 17-19B, and repeated description is omitted for reason of simplicity. Operations in block 126 and 128 are then performed to finish the fabrication of the structure 400.

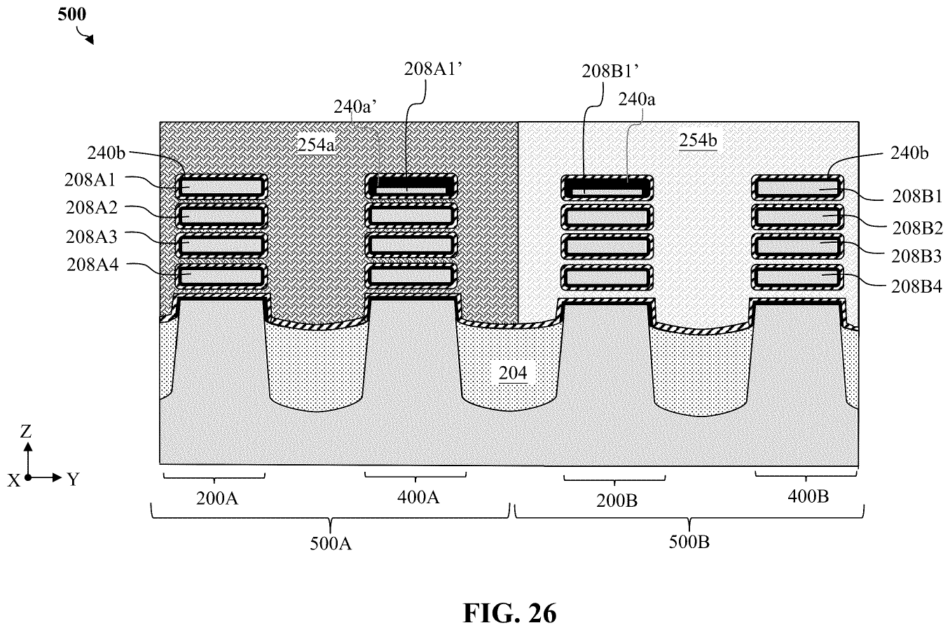

In the above embodiments described above, the structure (e.g., structure 200, 300 or 400) includes either PFETs including topmost channel member 208B1′ or NFETs including topmost channel member 208A1′. In an alternative embodiment represented by FIG. 26, a structure 500 includes a number of NFETs and a number of PFETs, at least one of the NFETs in a non-critical path include the topmost channel member 208A1′ and at least one of the PFETs in a non-critical path include topmost channel member 208B1′. For example, the structure 500 includes a first device region 500A for forming NFETs and a second device region 500B for forming PFETs. The first device region 500A includes a portion similar to the first device region 200A and a portion similar to the first device region 400A, and the second device region 500B includes a portion similar to the second device region 200B and a portion similar to the second device region 400B. Details of the first device regions 200A and 400A and the second device regions 200B and 400B have been described above, and repeated description is omitted for reason of simplicity. It is noted that the structure 500 may include one or more gate isolation features 260 configured to provide isolation between metal gate structures of two adjacent transistors.

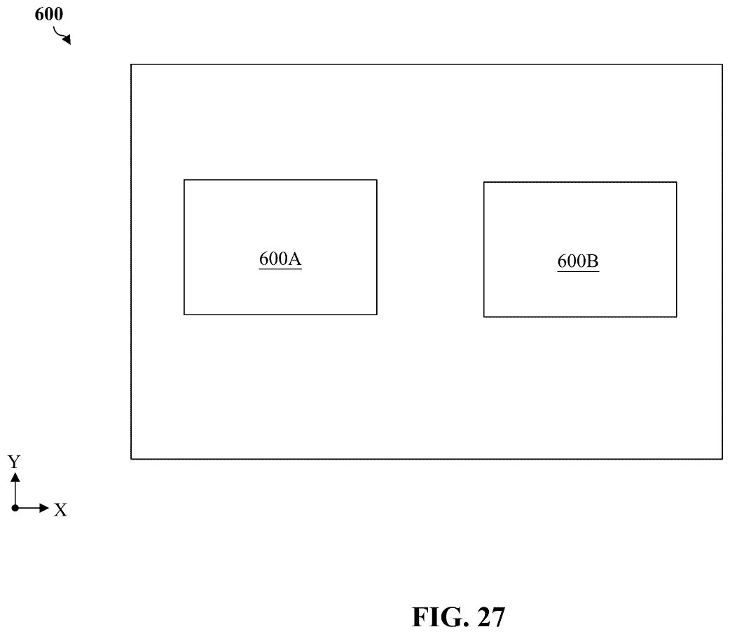

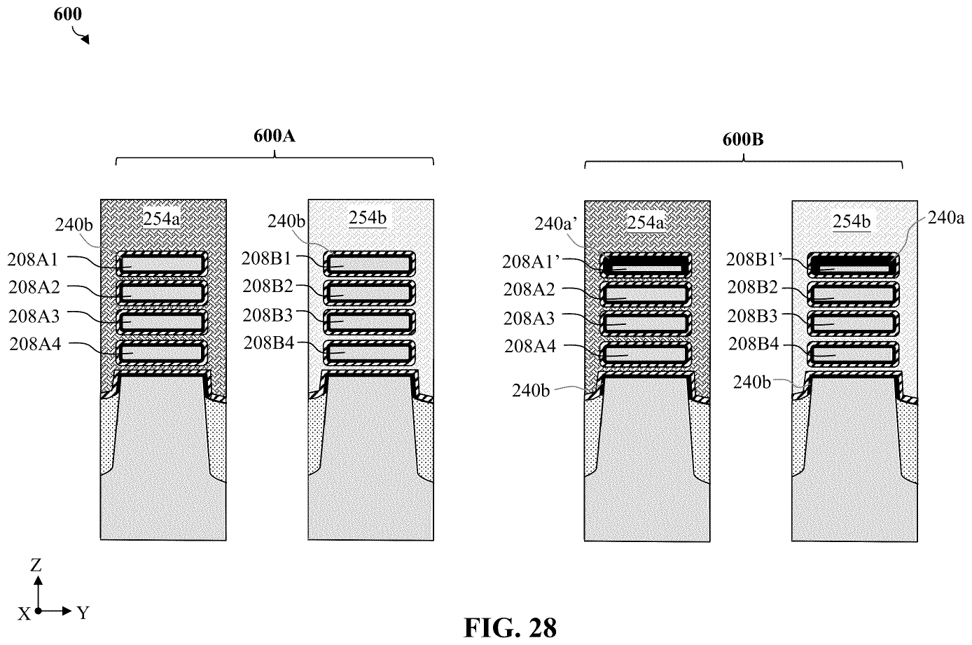

In the above embodiments, the structure (e.g., structure 200, 300, 400, or 500) is formed within a cell unit (e.g., memory cell, logic cell). In some other implementations, method 100 described above may be applied to form different blocks (or different chips) to achieve enhanced performance (e.g., reduced power loss or enhanced speed). FIG. 27 depicts a simplified structure (e.g., IC package) 600 including a first block 600A and a second block 600B, and FIG. 28 depict cross-sectional views of transistors in the first block 600A and cross-sectional views of transistors in the second block 600B. The first block 600A and the second block 600B may be configured to achieve different functions and/or may be used in different applications. For example, the first block 600A may include a die that cares more about speed than power consumption (e.g., dies having high-current drive ability or suitable for high-performance computing (HPC)), and the second block 600B may include a die that cares more about power consumption than speed (e.g., dies having low-current drive). For ease of description, the first block 600A may be referred to as a HPC block 600A, and the second block 600B may be referred to as a low power block 600B. However, it is understood that the method 100 can also be applied to form other types of dies. In the present disclosure, for performance boosting, the HPC block 600A may include NFETs having the topmost channel member 208A1 and PFETs having the topmost channel member 208B1, while the low power block 600B may include NFETs having the partially oxidized topmost channel member 208A1′ and PFETs having the partially oxidized topmost channel member 208B1′. Thus, both NFETs and PFETs of the HPC block 600A can obtain high current drive, and both NFETs and PFETs of the low power block 600B can achieve low power consumption. Details of the NFETs with the topmost channel member 208A1 or 208A1′ and details of the PFETs with the topmost channel member 208B1 or 208B1′ have been described above and repeated description is omitted for reason of simplicity.

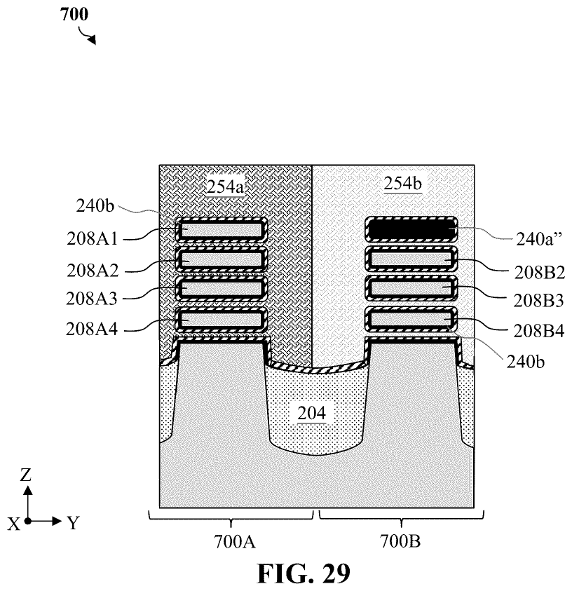

In the above embodiments, the topmost channel members 208A1′ and 208B1′ are formed by being partially oxidized. In another alternative embodiment, the topmost channel member 208A1 or 208B1 may be fully oxidized during the performing of the plasma treatment process 250. For example, with reference to FIG. 29, a structure 700 includes a first device region 700A including NFETs and a second device region 700B including PFETs, and the topmost channel member 208B1 is fully oxidized, thereby forming the interfacial layer 240a″ over the first middle channel member 208B2. In another alternative implementation, the topmost channel member 208A1 may be fully oxidized during the performing of the plasma treatment process 250. These two alternative embodiments represented by FIG. 29 may be applied to other embodiments (e.g., FIGS. 19A-28) described above. Although not shown, the method 100 may be applied to form transistors with other suitable numbers of channel members. For example, the stack 207 may include three channel layers 208 interleaved by three sacrificial layers 206, and a resulted transistor may include three channel members that do not undergo the plasma treatment process 250, while another resulted transistor may include three channel members, and a topmost channel member of the three channel members is partially or fully oxidized.

Although not intended to be limiting, one or more embodiments of the present disclosure provide many benefits to semiconductor devices and the formation thereof. In some embodiments, the present disclosure provides methods for forming transistors with reduced parasitic capacitance and improved performance (e.g., reduced performance gap between NFETs and PFETs, reduced power consumption). For example, a width and a thickness of a topmost channel member of the PFET are less than a width and a thickness of a bottommost channel member of the PFET. The smaller topmost channel member of the PFET may be achieved by performing a plasma treatment process to partially oxidize the initial topmost channel member. In some embodiments, NFETs and PFETs may be fabricated to have channel members with different configurations. For example, channel members for forming NFETs may not undergo the plasma treatment process and channel members for forming PFETs may undergo the plasma treatment process. This plasma treatment process may be implemented at a transistor level (e.g., within a cell) or at a die level (e.g., between two different dies). By oxidizing the topmost channel member, desired transistor performance may be achieved.

The present disclosure provides for many different embodiments. Semiconductor structures and methods of fabrication thereof are disclosed herein. In one exemplary aspect, the present disclosure is directed to a method. The method includes forming a plurality of nanostructures over a substrate, depositing a dielectric layer to wrap around the plurality of nanostructures, forming a mask layer over the dielectric layer, etching back the mask layer such that a top surface of the mask layer is coplanar with or lower than a top surface of a topmost nanostructure of the plurality of nanostructures, performing a treatment to reduce a thickness of the topmost nanostructure of the plurality of nanostructures, after the performing of the treatment, selectively removing the mask layer, and forming a gate electrode over the dielectric layer to wrap around the plurality of nanostructures.

In some embodiments, the performing of the treatment may implement a directional plasma including an oxygen-containing gas. In some embodiments, the dielectric layer may include an interfacial layer and a high-K dielectric layer over the interfacial layer, and the performing of the treatment may change a thickness of the interfacial layer. In some embodiments, after the performing of the treatment, a ratio of a thickness of the topmost nanostructure of the plurality of nanostructures to a thickness of a bottommost nanostructure of the plurality of nanostructures may be less than 0.8. In some embodiments, after the performing of the treatment, a width of the topmost nanostructure of the plurality of nanostructures may be less than a width of a bottommost nanostructure of the plurality of nanostructures. In some embodiments, the forming of the plurality of nanostructures may include forming a plurality of channel layers interleaved by a plurality of sacrificial layers, selectively removing the plurality of sacrificial layers to form a plurality of openings, forming a plurality of dummy layers in the plurality of openings, and selectively removing the plurality of dummy layers to release the plurality of channel layers as the plurality of nanostructures, wherein etch selectivity between the plurality of channel layers and the plurality of dummy layers is greater than etch selectivity between the plurality of channel layers and the plurality of sacrificial layers. In some embodiments, after the etching back, a top surface of the mask layer may be substantially coplanar with a bottom surface of the topmost nanostructure of the plurality of nanostructures. In some embodiments, the method may also include forming source/drain features coupled to the plurality of nanostructures, and forming inner spacer features under the topmost nanostructure of the plurality of nanostructures to provide isolation between the source/drain features and the gate electrode, and in a cross-sectional view cut through the source/drain features and the plurality of nanostructures, a thickness of the topmost nanostructure of the plurality of nanostructures is non-uniform. In some embodiments, the source/drain features comprise P-type dopants.

In another exemplary aspect, the present disclosure is directed to a method. The method includes forming a first plurality of nanostructures over a first region of a substrate and a second plurality of nanostructures over a second region of the substrate, wherein the first plurality of nanostructures and the second plurality of nanostructures comprise a same number of nanostructures, partially oxidizing a topmost nanostructure of the second plurality of nanostructures from top to bottom, forming a dielectric layer to wrap around the first plurality of nanostructures and the second plurality of nanostructures, forming a first gate electrode to wrap around and over the first plurality of nanostructures, and forming a second gate electrode to wrap around and over the second plurality of nanostructures, after the partially oxidizing, a top surface of the topmost nanostructure of the second plurality of nanostructures is lower than a top surface of a topmost nanostructure of the first plurality of nanostructures, and a bottom surface of the topmost nanostructure of the second plurality of nanostructures is substantially coplanar with a bottom surface of the topmost nanostructure of the first plurality of nanostructures.

In some embodiments, the method may also include forming first-type source/drain features coupled to the first plurality of nanostructures, and forming second-type source/drain features coupled to the second plurality of nanostructures, the first-type source/drain features and the second-type source/drain features may include dopants with different doping polarities. In some embodiments, after the partially oxidizing, a bottom surface of the topmost nanostructure of the second plurality of nanostructures may be substantially coplanar with a bottom surface of the topmost nanostructure of the first plurality of nanostructures. In some embodiments, a width of the topmost nanostructure of the second plurality of nanostructures may be less than a width of a bottommost nanostructure of the second plurality of nanostructures. In some embodiments, the forming of the dielectric layer may be performed prior to the partially oxidizing. In some embodiments, the forming of the dielectric layer may include forming a first interfacial layer wrapping around the first plurality of nanostructures and a second interfacial layer wrapping around the second plurality of nanostructures, and conformally depositing a high-K dielectric layer over the first and second interfacial layers, where the partially oxidizing of the topmost nanostructure of the second plurality of nanostructures increases a thickness of portion of the second interfacial layer disposed over the topmost nanostructure of the second plurality of nanostructures. In some embodiments, the partially oxidizing of the topmost nanostructure of the second plurality of nanostructures from top to bottom may include forming a mask layer over the substrate, recessing a portion of the mask layer formed over the second region of the substrate, wherein a top surface of the recessed portion of the mask layer is lower than a top surface of the topmost nanostructure of the second plurality of nanostructures, and performing a directional plasma process to oxidize the topmost nanostructure of the second plurality of nanostructures.

In yet another exemplary aspect, the present disclosure is directed to a semiconductor structure. The semiconductor structure includes a transistor comprising a plurality of nanostructures over a substrate, a gate dielectric layer wrapping around and over the plurality of nanostructures, and a gate electrode over the gate dielectric layer, where a portion of the gate dielectric layer extending over a top surface of the topmost nanostructure is thicker than a portion of the gate dielectric layer disposed extending under a bottom surface of the topmost nanostructure.

In some embodiments, a thickness of a topmost nanostructure of the plurality of nanostructures may be less than a thickness of a bottommost nanostructure of the plurality of nanostructures, and a distance between the topmost nanostructure of the plurality of nanostructures and a nanostructure immediately under the topmost nanostructure may be equal to a distance between the bottommost nanostructure of the plurality of nanostructures and the substrate. In some embodiments, a width of the topmost nanostructure may be less than a width of the bottommost nanostructure. In some embodiments, the transistor is a P-type transistor, and the semiconductor structure may also include an N-type transistor including another plurality of nanostructures over the substrate, and a top surface of the topmost nanostructure may be lower than a top surface of a topmost nanostructure of the another plurality of nanostructures.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
forming a plurality of nanostructures over a substrate;
depositing a dielectric layer to wrap around the plurality of nanostructures;
forming a mask layer over the dielectric layer;
etching back the mask layer such that a top surface of the mask layer is coplanar with or lower than a top surface of a topmost nanostructure of the plurality of nanostructures;
performing a treatment to reduce a thickness of the topmost nanostructure of the plurality of nanostructures;
after the performing of the treatment, selectively removing the mask layer; and
forming a gate electrode over the dielectric layer to wrap around the plurality of nanostructures.

2. The method of claim 1, wherein the performing of the treatment implements a directional plasma including an oxygen-containing gas.

3. The method of claim 1, wherein the dielectric layer comprises an interfacial layer and a high-K dielectric layer over the interfacial layer, and the performing of the treatment changes a thickness of the interfacial layer.

4. The method of claim 1, wherein, after the performing of the treatment, a ratio of a thickness of the topmost nanostructure of the plurality of nanostructures to a thickness of a bottommost nanostructure of the plurality of nanostructures is less than 0.8.

5. The method of claim 1, wherein, after the performing of the treatment, a width of the topmost nanostructure of the plurality of nanostructures is less than a width of a bottommost nanostructure of the plurality of nanostructures.

6. The method of claim 1, wherein the forming of the plurality of nanostructures comprises:
forming a plurality of channel layers interleaved by a plurality of sacrificial layers;
selectively removing the plurality of sacrificial layers to form a plurality of openings;
forming a plurality of dummy layers in the plurality of openings; and
selectively removing the plurality of dummy layers to release the plurality of channel layers as the plurality of nanostructures, wherein etch selectivity between the plurality of channel layers and the plurality of dummy layers is greater than etch selectivity between the plurality of channel layers and the plurality of sacrificial layers.

7. The method of claim 1, wherein, after the etching back, a top surface of the mask layer is substantially coplanar with a bottom surface of the topmost nanostructure of the plurality of nanostructures.

8. The method of claim 1, further comprising:
forming source/drain features coupled to the plurality of nanostructures; and
forming inner spacer features under the topmost nanostructure of the plurality of nanostructures to provide isolation between the source/drain features and the gate electrode,
wherein in a cross-sectional view cut through the source/drain features and the plurality of nanostructures, a thickness of the topmost nanostructure of the plurality of nanostructures is non-uniform.

9. The method of claim 8, wherein the source/drain features comprise P-type dopants.

10. A method, comprising:
forming a first plurality of nanostructures over a first region of a substrate and a second plurality of nanostructures over a second region of the substrate, wherein the first plurality of nanostructures and the second plurality of nanostructures comprise a same number of nanostructures;
partially oxidizing a topmost nanostructure of the second plurality of nanostructures from top to bottom;
forming a dielectric layer to wrap around the first plurality of nanostructures and the second plurality of nanostructures;
forming a first gate electrode to wrap around and over the first plurality of nanostructures; and
forming a second gate electrode to wrap around and over the second plurality of nanostructures,
wherein, after the partially oxidizing, a top surface of the topmost nanostructure of the second plurality of nanostructures is lower than a top surface of a topmost nanostructure of the first plurality of nanostructures, and a bottom surface of the topmost nanostructure of the second plurality of nanostructures is substantially coplanar with a bottom surface of the topmost nanostructure of the first plurality of nanostructures.

11. The method of claim 10, further comprising:
forming first-type source/drain features coupled to the first plurality of nanostructures; and
forming second-type source/drain features coupled to the second plurality of nanostructures, wherein the first-type source/drain features and the second-type source/drain features comprise dopants with different doping polarities.

12. The method of claim 11, wherein, after the partially oxidizing, a bottom surface of the topmost nanostructure of the second plurality of nanostructures is substantially coplanar with a bottom surface of the topmost nanostructure of the first plurality of nanostructures.

13. The method of claim 10, wherein a width of the topmost nanostructure of the second plurality of nanostructures is less than a width of a bottommost nanostructure of the second plurality of nanostructures.

14. The method of claim 10, wherein the forming of the dielectric layer is performed prior to the partially oxidizing.

15. The method of claim 10, wherein the forming of the dielectric layer comprises:
forming a first interfacial layer wrapping around the first plurality of nanostructures and a second interfacial layer wrapping around the second plurality of nanostructures; and
conformally depositing a high-K dielectric layer over the first and second interfacial layers,
wherein the partially oxidizing of the topmost nanostructure of the second plurality of nanostructures increases a thickness of portion of the second interfacial layer disposed over the topmost nanostructure of the second plurality of nanostructures.

16. The method of claim 10, wherein the partially oxidizing of the topmost nanostructure of the second plurality of nanostructures from top to bottom comprises:
forming a mask layer over the substrate;
recessing a portion of the mask layer formed over the second region of the substrate, wherein a top surface of the recessed portion of the mask layer is lower than a top surface of the topmost nanostructure of the second plurality of nanostructures; and
performing a directional plasma process to oxidize the topmost nanostructure of the second plurality of nanostructures.

17. A semiconductor structure, comprising:
a transistor comprising:
a plurality of nanostructures over a substrate,
a gate dielectric layer wrapping around and over the plurality of nanostructures, and
a gate electrode over the gate dielectric layer,
wherein a portion of the gate dielectric layer extending over a top surface of a topmost nanostructure is thicker than a portion of the gate dielectric layer disposed extending under a bottom surface of the topmost nanostructure.

18. The semiconductor structure of claim 17, wherein a thickness of the topmost nanostructure of the plurality of nanostructures is less than a thickness of a bottommost nanostructure of the plurality of nanostructures, and a distance between the topmost nanostructure of the plurality of nanostructures and a nanostructure immediately under the topmost nanostructure is equal to a distance between the bottommost nanostructure of the plurality of nanostructures and the substrate.

19. The semiconductor structure of claim 18, wherein a width of the topmost nanostructure is less than a width of the bottommost nanostructure.

20. The semiconductor structure of claim 18,
wherein the transistor is a P-type transistor, and the semiconductor structure further comprises an N-type transistor including another plurality of nanostructures over the substrate, and
wherein a top surface of the topmost nanostructure is lower than a top surface of a topmost nanostructure of the another plurality of nanostructures.
